(19) United States
(12) Patent Application Publication
(10) Pub. No.: US 2006/0021570 A1
(43) Pub. Date: Feb. 2, 2006

(54) Reduction in size of hemispherical grains of hemispherical grained film

(76) Inventors: Kazuhide Hasebe, Tokyo-To (JP); Norifumi Kimura, Tokyo-To (JP); Takehiko Fujita, Tokyo-To (JP); Yoshikazu Furusawa, Tokyo-To (JP)

Correspondence Address: SMITH, GAMBRELL & RUSSELL, LLP, 1850 M STREET, N.W., SUITE 800, WASHINGTON, DC, 20036, US

(21) Appl. No.: 11/192,312

(22) Filed: Jul. 29, 2005

(30) Foreign Application Priority Data
Aug. 2, 2004 (JP) 2004-225050
Jun. 13, 2005 (JP) 2005-173035

(51) Int. Cl. C30B 23/00; B05C 11/00; H01L 21/26

(52) U.S. Cl. 118/697; 438/798; 117/97

(57) ABSTRACT

A hemispherical grained (HSG) film is oxidized to form an oxidized layer at the surface part of the HSG film, and then the oxidized layer is etched to be removed. The size of the hemispherical grains after etching is smaller than that as formed.

### BACKGROUND OF THE INVENTION

1. Field of the Invention

The present invention relates to a method, an apparatus and a storage medium storing a control program for forming a hemispherical grained (HSG) film, which is preferably used as an electrode of a capacitor, and more particularly to a technique for reducing the size of hemispherical grains of the HSG film.

2. Description of the Related Art

In order to form a semiconductor integrated circuit, in general, a semiconductor wafer or a glass substrate is repeatedly subjected to a film-forming process, an etching process, a heat-diffusion process, and an oxidizing process, whereby desired transistor elements, resistive elements, or capacitor elements are formed on a surface of the semiconductor wafer or the glass substrate in a high-density integration.

Recently, each element of a semiconductor device has been further miniaturized to cope with a higher integration of the semiconductor device. In a storage device such as a DRAM, an area occupied by each cell becomes smaller and smaller. In order to secure a sufficient capacity with the smaller occupied area, a smaller thickness of the dielectric insulation layer between capacitor electrodes and/or a greater dielectric constant of the dielectric material of the insulation layer is required. However, a smaller thickness of the insulation layer is likely to result in the deterioration in its insulation performance. In addition, there are various technical difficulties of forming a dielectric material of a high dielectric constant.

In order to solve the above problem, a polysilicon film having a surface with fine irregularities has been recently formed on the electrode of the capacitor. Such irregularities double or triple the actual surface area of the electrode, which increases the capacity of the capacitor. Thus, a high capacity of the capacitor can be achieved even if the occupied area thereof is small. JP5-304273A, JP7-221034A and JP2002-222871A disclose methods of forming an HSG polysilicon film as the aforementioned polysilicon film with fine irregularities

A typical example of a method of forming an HSG polysilicon film on a surface of an electrode of a capacitor will be briefly described with reference to FIG. 7. As shown in FIG. 7(A), an interlayer insulation film 2 is formed on a silicon wafer W. A lower electrode 4 of a capacitor is formed on the interlayer insulation film 2 and penetrates the insulation film 2. The lower electrode 4 is formed of polysilicon doped with impurities such as phosphorus, and has a cylindrical shape adapted to a so-called “stack capacitor” structure. The lower electrode 4 is electrically connected to a source (not shown) formed on the wafer W.

A silane-series gas such as monosilane gas is irradiated to the surface of the silicon wafer W structured as shown in FIG. 7(A) to form an amorphous silicon film, and silicon crystal nuclei are seeded on the surface of the amorphous silicon film and grow due to the migration of silicon atoms, thereby, an HSG film having a number of crystalline hemispherical grains 6 of a high grain distribution density (i.e., the number of the grains 6 per unit area) is formed on the lower electrode 4 as shown in FIG. 7(B). As the hemispherical grains 6 significantly increase the actual surface area of the lower electrode 4, a large capacity of the capacitor can be achieved even if the occupied space thereof is small. Note that an insulation film and an upper electrode are further formed on the lower electrode to complete the capacitor, which are omitted in FIG. 7.

As stated above, the hemispherical grains 6 formed on the electrode of a capacitor can double or triple the capacity of the capacitor for a certain occupied space, as compared with that of a conventional capacitor.

The diameter D1 of each hemispherical grain 6 is determined by the nuclei density and the deposition amount of the silicon film. In general, the diameter D1 is about 50 nm. The diameter D1 of about 50 nm conforms to non-strict design rules, but is too large to conform to strict design rules with a finer scale established in response to a demand for further miniaturization. For example, if the inner diameter H1 of the cylinder of the lower electrode 4 is decreased to about 100 nm, or if the grain distribution density is increased, the appearance of the grains of 50 nm diameter results in deterioration in the step coverage of the capacitor insulation film which is formed in the subsequent process step, or in a short circuit between adjacent lower electrodes.

### SUMMARY OF THE INVENTION

The present invention is made in view of the above problems to effectively solve the same, and therefore a generic object of the present invention is to provide an HSG film having hemispherical grains of a smaller size.

In order to solve the above objective, the present invention provides a film-forming method including: (a) irradiating a film-forming gas to a surface of a process object to seed crystal nuclei, and causing growth of the nuclei, thereby forming a hemispherical grained film having hemispherical crystal grains on the surface of the process object; (b) oxidizing a surface part of the hemispherical grained film, thereby forming an oxidized layer at the surface part of the hemispherical grained film; and (c) etching the oxidized layer to remove the same.

The size of hemispherical grains can be reduced, by oxidizing and etching steps.

In the method, the steps (a), (b) and (c) may be performed in a common processing vessel. Alternatively, at least two of the steps (a), (b) and (c) may be performed in processing vessels different from each other.

In the step (c), a dry etch may be performed by using hydrogen fluoride (HF) gas. Alternatively, in the step (c), a wet etch may be performed by using diluted hydrofluoric acid (DHF).

The hemispherical grained film may be doped with impurities. The hemispherical grained film may be doped with impurities between the steps (a) and (b). Alternatively, the hemispherical grained film may be doped with impurities in the step (a).

For example, a base part of the hemispherical grained film may comprise amorphous silicon and the crystalline hemispherical grains may comprise crystalline silicon

The present invention further provides a film-forming apparatus including: a processing vessel adapted to contain a process object and adapted to be evacuated; a support member adapted to support the process object in the processing vessel; a film-forming gas supply system adapted to supply a film-forming gas into the processing vessel; an oxidizing gas supply system adapted to supply an oxidizing gas into the processing vessel; an etching gas supply system adapted to supply an etching gas into the processing vessel; a heater adapted to heat the process object contained in the processing vessel; and a controller (a) configured to control the film-forming gas supply system to irradiate the film-forming gas to a surface of a process object to seed crystal nuclei, and causing growth of the nuclei, thereby forming a hemispherical grained film having hemispherical crystal grains on the surface of the process object; (b) configured to control the oxidizing gas supply system to oxidize a surface part of the hemispherical grained film, thereby forming an oxidized layer at the surface part of the hemispherical grained film; and (c) configured to control the etching gas supply system to etch the oxidized layer to remove the same.

The present invention further provides a data storage medium storing a control program therein, wherein, upon execution of the control program by a control computer of a film-forming apparatus, the film forming apparatus performs a film-forming method including: (a) irradiating a film-forming gas to a surface of a process object to seed crystal nuclei, and causing growth of the nuclei, thereby forming a hemispherical grained film having crystalline hemispherical grains on the surface of the process object; (b) oxidizing a surface part of the hemispherical grained film, thereby forming an oxidized layer at the surface part of the hemispherical grained film; and (c) etching the oxidized layer to remove the same.

### BRIEF DESCRIPTION OF THE DRAWINGS

FIG. 1 schematically shows the structure of a film-forming apparatus in one embodiment of the present invention;

FIG. 2 is a time chart showing a sequence of operations for carrying out a method according to the present invention in the first embodiment;

FIGS. 3(A) to 3(E) are schematic cross-sectional views showing the formation of crystalline hemispherical grains and the change in the shape thereof;

FIG. 4 is a time chart showing a sequence of operations for carrying out a method according to the present invention in the second embodiment;

FIG. 5 is an electron micrograph of hemispherical grains, which is taken immediately after the grains are formed;

FIG. 6 is an electron micrograph of the hemispherical grains, which is taken after the grains are subjected to an oxidizing step and an etching step; and

FIGS. 7(A) and 7(B) show an example of a method of forming an HSG film on a surface of an electrode of a capacitor.

### DETAILED DESCRIPTION OF THE PREFERRED EMBODIMENTS

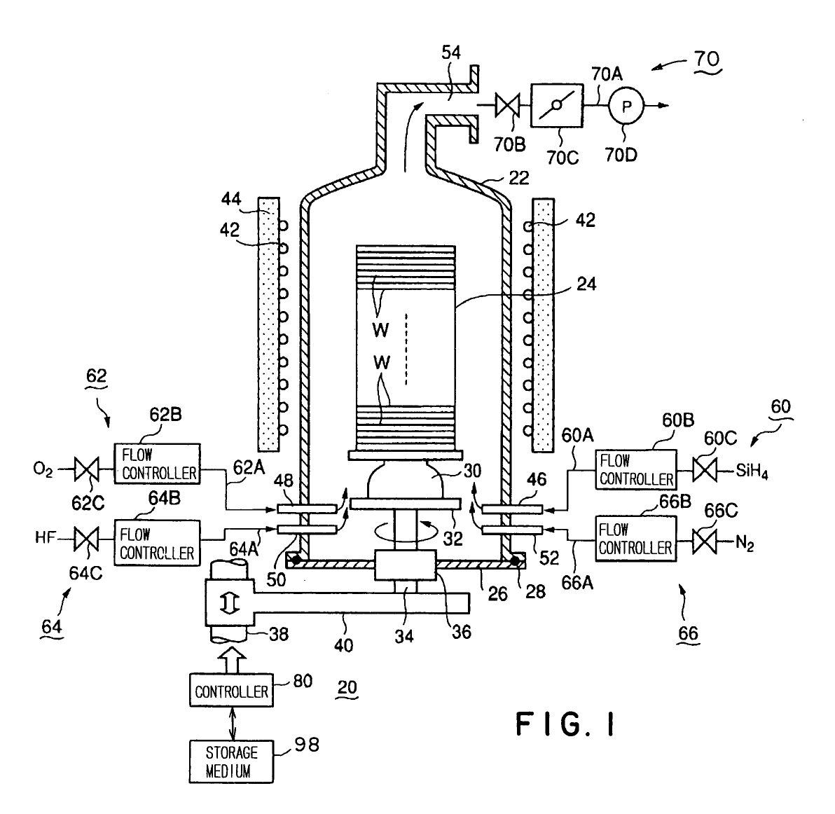

The film-forming apparatus shown in FIG. 1 is adapted to continuously perform a hemispherical grained (HSG) film forming step, an oxidized layer forming step and an etching step. The film-forming apparatus 20 includes a cylindrical vertical processing vessel 22 of a predetermined vertical length having a lower end opening. The processing vessel 22 may be made of heat-resistant quartz. A wafer boat 24, serving as a wafer support member, supports thereon a plurality of semiconductor wafers W, i.e., process objects, at vertical intervals. The wafer boat 24 moves vertically to be loaded into and unloaded from the processing vessel 22 through the lower end opening thereof. Typically, the wafer boat 24 is made of quartz, and is capable of supporting about 50 to 100 pieces of wafers W each having a diameter of 300 mm at regular vertical intervals.

After the wafer boat 24 is loaded into the processing vessel 22, the lower end opening of the processing vessel 22 is hermetically closed by a cover 26, which may be formed of a quartz plate or a stainless steel plate. A sealing member 28 such as an O-ring is interposed between the lower end of the processing vessel 22 and the cover 26 to hermetically seal the gap therebetween. The wafer boat 24 is mounted on a table 32 through a heat insulating tube 30 made of quartz. The table 32 is supported on the upper end of a rotary shaft 34, which passes through the cover 26. A magnetic fluid seal 36 is attached to a part of the cover 26 where the rotary shaft 34 passes therethrough, so as to hermetically seal the gap between the cover 26 and the rotary shaft 34 while allowing rotation of the rotary shaft 34. The rotary shaft 34 is mounted to a distal end of an arm 40 supported on an elevating mechanism 38 such as a boat elevator. Thus, the wafer boat 24 and the cover 26 can be vertically moved together. Alternatively, the table 32 may be fixedly mounted to the cover 26 so as to process the wafers W without rotating the wafer boat 24.

A heater 42, which may comprise carbon wires, surrounds the processing vessel 22, so as to heat the processing vessel 22 located inside the heater 42 and the semiconductor wafers W contained in the processing vessel 22. A heat insulating material 44 is disposed around the outer circumference of the heater 42, so that a thermal stability of the processing vessel 22 can be provided. First to fourth gas nozzles 46, 48, 50 and 52, which may be made of quartz, penetrate a lower part of the circumferential wall of the processing vessel 22, and are hermetically sealed with respect to the processing vessel 22. An exhaust port 54 transversely bent into an L-shape is arranged on the ceiling part of the processing vessel 22.

A film-forming gas supply system 60 is connected to the first gas nozzle 46; an oxidizing gas supply system 62 is connected to the second gas nozzle 48; an etching gas supply system 64 is connected to the third gas nozzle 50; and an inert gas supply system 66 for supplying an inert gas such as N₂ (nitrogen) gas is connected to the fourth gas nozzle 52. Ar (Argon) gas or He (Helium) gas may be also used as the inert gas.

The film-forming gas supply system 60, the oxidizing gas supply system 62, the etching gas supply system 64 and the inert gas supply system 66 respectively include gas lines 60A, 62A, 64A and 66A which are respectively connected to the first to fourth gas nozzles 46, 48, 50 and 52, and which are respectively provided with flow controllers (e.g., mass-flow controllers) 60B, 62B, 64B and 66B and shutoff valves 60C, 62C, 64C and 66C. Thus, the systems 60, 62, 64 and 66 can supply respective gases with controlled flow rates on demand. In the illustrated embodiment, an Si (silicon)-containing gas such as SiH₄ (monosilane) gas is used as the film-forming gas; O₂ (oxygen) gas is used as the oxidizing gas; and HF (hydrogen fluoride) gas, which is capable of selectively etching an SiO₂ (silicon dioxide) film, is used as the etching gas.

Connected to the exhaust port 54A is a vacuum exhaust system 70 for evacuating the processing vessel 22, which includes a gas passage 70A provided thereon with a shutoff valve 70B, a pressure control valve 70C such as a butterfly valve, and a vacuum pump 70D. The operation of the film-forming apparatus 20 is controlled by a controller 80, or a control computer such as a microcomputer. The controller 80 includes a storage medium 98 such as a floppy disk or a flush memory, for storing a control program for controlling the operation of the film-forming apparatus 20.

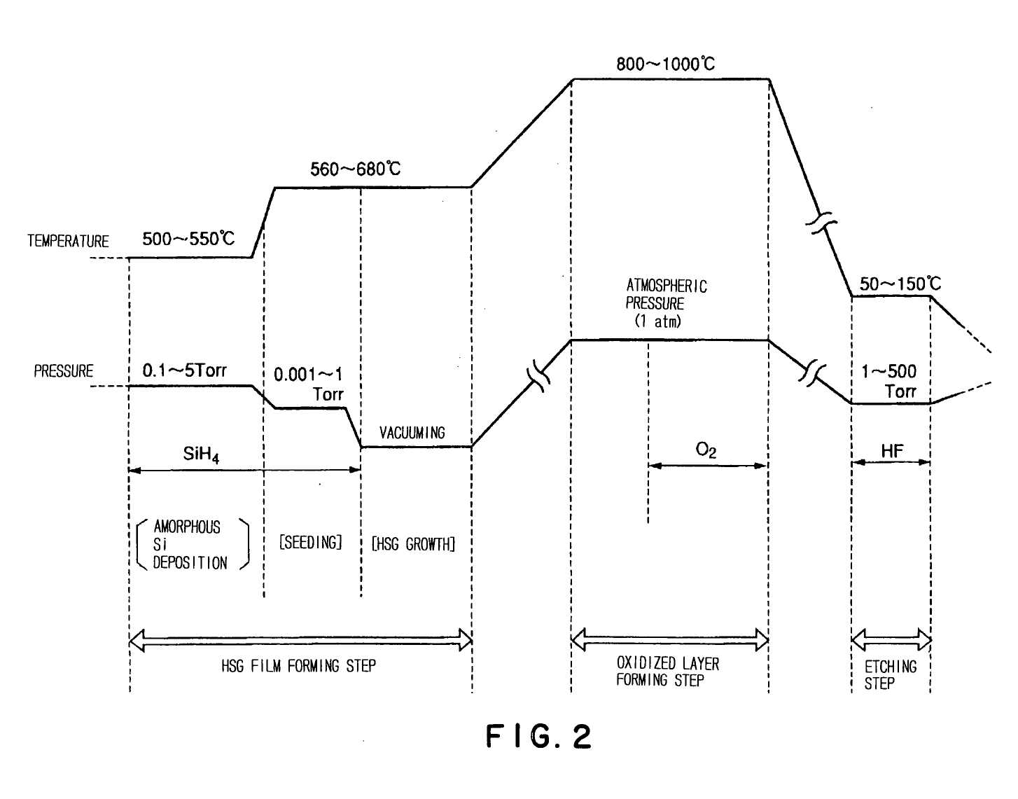

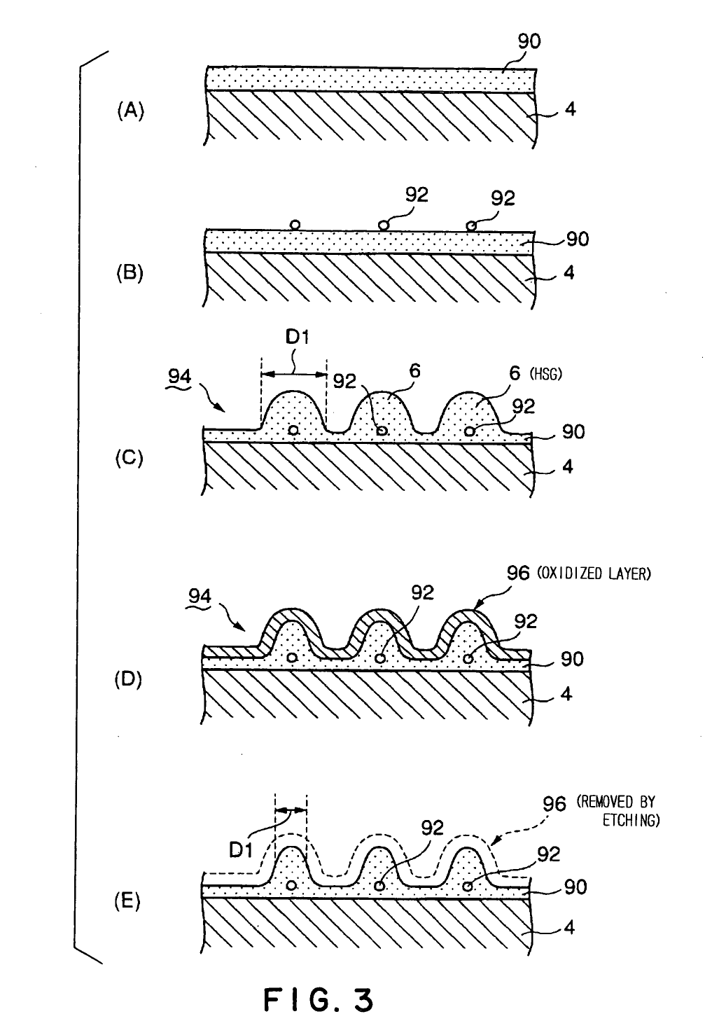

The first embodiment of the film-forming method according to the present invention, in which respective process steps are successively performed by using the single film-forming apparatus 20, will be described with reference to FIGS. 2 and 3.

In order to carry out the film-forming method, the operation of the film-forming apparatus 20 is controlled by the controller 80 that executes the control program stored in the storage medium 98. The process flow scheme is as follows.

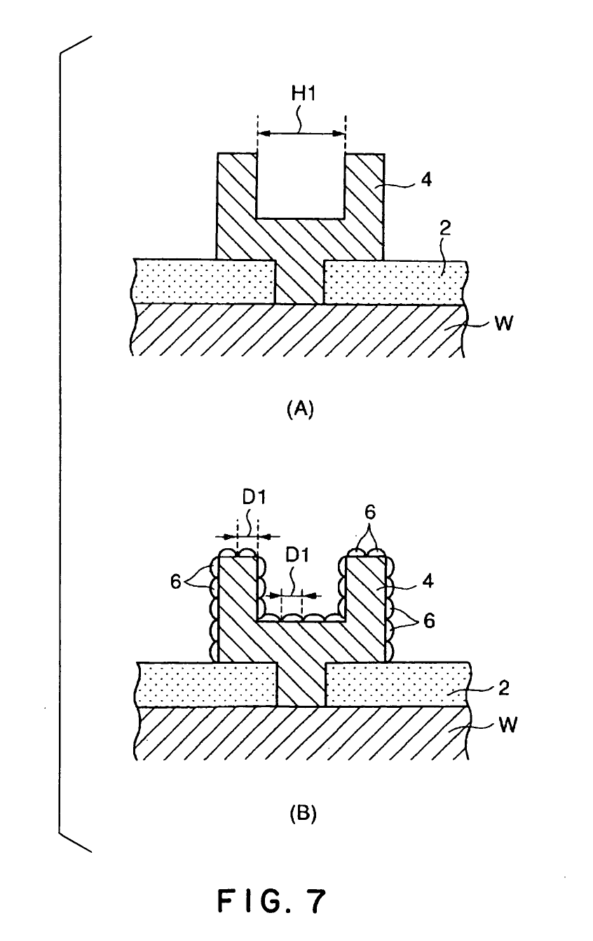

The surface of each of the wafers W has been previously processed as shown in FIG. 7(A). That is, a number of lower electrodes 4, formed of a phosphorus-doped amorphous silicon, each having a cylindrical shape adapted to a so-called “stack capacitor” structure are arrayed on the surface of the semiconductor wafer W, or a silicon substrate.

Before the wafers W are loaded in the processing vessel 22 and the film-forming apparatus 20 is in a stand-by condition, the processing vessel 22 is heated to be maintained at a temperature lower than the process temperature. The wafer boat 24 supporting thereon a plurality of, e.g., 50 wafers W of a room temperature is raised from below the processing vessel 22 whose walls have been heated, so that the wafer boat 24 is loaded into the processing vessel 22. Then, the lower end opening of the processing vessel 22 is closed by the cover 26 to hermetically close the processing vessel 22.

Then, the processing vessel 22 is evacuated and maintained at a predetermined process pressure, and the electric power supplied to the heater 42 is increased to raise the temperature of the wafer W to a temperature suitable for the film-forming process. After the temperature of the wafers W is stabilized, the HSG film forming step, the oxidized layer forming step, and the etching step are consecutively performed in that order. FIG. 2 shows changes in process temperature and process pressure in the respective process steps. In the above process steps, a suitable process gas or gases are supplied into the processing vessel 22. That is, SiH₄ gas is supplied from the first gas nozzle 46 connected to the film-forming gas supply system 60. O₂ gas is supplied from the second gas nozzle 48 connected to the oxidizing gas supply system 62. HF gas is supplied from the third gas nozzle 50 connected to the etching gas supply system 64. N₂ gas is supplied from the fourth gas nozzle 52 connected to the inert gas supply system 66, on demand.

Each of the process steps of the film forming method will be described in detail.

HSG Film Forming Step

The HSG film forming step includes an amorphous silicon film forming step, a nuclei seeding step, and a hemispherical grain growing step. SiH₄ gas is used in the amorphous silicon film forming step and the nuclei seeding step. N₂ gas also may be used in these two steps.

After the temperature of the wafers W is stabilized at a predetermined temperature, the supply of SiH₄ gas is started to form an amorphous silicon film on the surface of the wafers W. As shown in FIG. 3(A), an amorphous silicon film 90 is deposited at a relatively low deposition rate on the surfaces of the lower electrodes 4 which are typically formed of a polysilicon. In this process step, the flow rate of SiH₄ gas may be in the range of 50 sccm to 4,000 sccm. The process temperature may be in the range of 500° C. to 550° C., and the process pressure may be in the range of 0.1 Torr (13 Pa) to 5 Torr (665 Pa).

After depositing the amorphous silicon film 90 for a predetermined time period, the nuclei seeding step is performed by slightly raising the process temperature and slightly lowering the process pressure, while the supply of the SiH₄ gas is continued. In the nuclei seeding step, as shown in FIG. 3(B), a plurality of silicon crystal nuclei 92 are formed on the amorphous silicon film 90. In this step, the process temperature may be in the range of from 560° C. to 680° C., and the process pressure may be in the range of from 0.001 Torr to 1 Torr.

After seeding nuclei for a predetermined time period, the hemispherical grain growing step is performed by stopping the supply of all the gases while continuing the evacuation of the processing vessel 22 (this operation is referred to as “vacuuming”), while maintaining the process temperature. That is, the supply of SiH₄ gas is stopped, and if N₂ gas is supplied in the nuclei seeding step, the supply of N₂ gas is also stopped. The pressure in the processing vessel 22 is significantly lowered by the vacuuming, so that silicon atoms in the amorphous silicon film 90 migrate to aggregate around the crystal nuclei 92, crystalline hemispherical grains 6 grow around the crystal nuclei 92, and thus an HSG film 94 is formed, as shown in FIG. 3(C). Each of the hemispherical grains 6 comprises crystalline silicon, while the base part 90 of the hemispherical grained film 94 comprises amorphous silicon. Typically, each of the hemispherical grains 6 comprises a single or a few silicon crystals; and most hemispherical grains 6 are monocrystalline, while some hemispherical grains 6 are polycrystalline ones with a few crystals.

As will be readily understood by those skilled in the art, the process conditions of the HSG film forming step are given as a mere example, and are thus not limited thereto.

As previously mentioned in the “background of the invention”, the diameter D1 of the grains 6 is about 50 nm on the average, which is too large to meet severe design rules.

After causing growth of the hemispherical grains for a predetermined time period, the HSG film forming step is completed. Subsequently, the oxidized layer forming step is performed.

Oxidized Layer Forming Step

The oxidized layer forming step will be described. After the completion of the HSG film forming step, gases remaining in the processing vessel 22 are discharged therefrom by carrying out the aforementioned vacuuming, or by carrying out a cycle purging that intermittently supplies N₂ gas while evacuating the processing vessel 22 continuously. The supply of SiH₄ gas, of course, remains stopped. Then, the process temperature is raised to about 800° C. to 1,000° C., and the process pressure is raised to about the atmospheric pressure by supplying N₂ gas into the processing vessel 22. After the process temperature and the process pressure become stable, the supply of O₂ gas as an oxidizing gas is started. Thus, the surface parts of the grains 6 and the surface part of the base part of the HSG film 94 (remaining amorphous silicon film 90) are oxidized, so that a thin oxidized layer (SiO₂) 96, or an oxidized film, is formed over the surface part of the HSG film 94, as shown in FIG. 3(D). In this process step, the flow rate of the O₂ gas is in the range of 100 sccm to 10,000 sccm. The process period (time) is in the range of from about 1 minute to 120 minutes, which varies depending on the desired thickness of the oxidized layer 96. After forming the oxidized layer 96, the etching step is performed.

Etching Step

The etching step will be described. After the completion of the oxidized layer forming step, gases remaining in the processing vessel 22 are discharged therefrom by stopping the supply of the O₂ gas; and by carrying out a vacuuming process, or by carrying out a cycle purging that intermittently supplies N₂ gas into the processing vessel 22 while evacuating the processing vessel 22 continuously. Then, the process temperature is lowered to about 50° C. to 150° C., and the process pressure is lowered to 1 Torr to 500 Torr. After the process temperature and the process pressure become stable, the supply of HF (hydrogen fluoride) gas is started. As HF gas selectively etches the oxidized layer 96 of SiO₂, the oxidized layer 96 formed in the precedent process step is entirely removed by a dry etch, as shown in FIG. 3(E). As a result, the diameter D1 of the crystal grain 6 is reduced. In this process step, the flow rate of HF gas is in the range of 100 sccm to 10,000 sccm. If necessary, N₂ gas is supplied to dilute HF gas.

According to the above embodiment of the present invention, the diameter D1 of the hemispherical grains 6 can be remarkably reduced, by forming the oxidized layer 96 at the surface part of each hemispherical grain 6 and thereafter selectively removing only the oxidized layer 96 by etching. Accordingly, even if the scale of the design rule is severely lessened, problems on the step coverage of a capacitor insulation film will not occur, and short circuit between adjacent lower electrodes can be prevented.

In addition, all the above-described process steps can be performed in a common film-forming apparatus 20, which results in improved throughput and reduction in the cost of equipment.

Next, the second embodiment of the present invention will be described below.

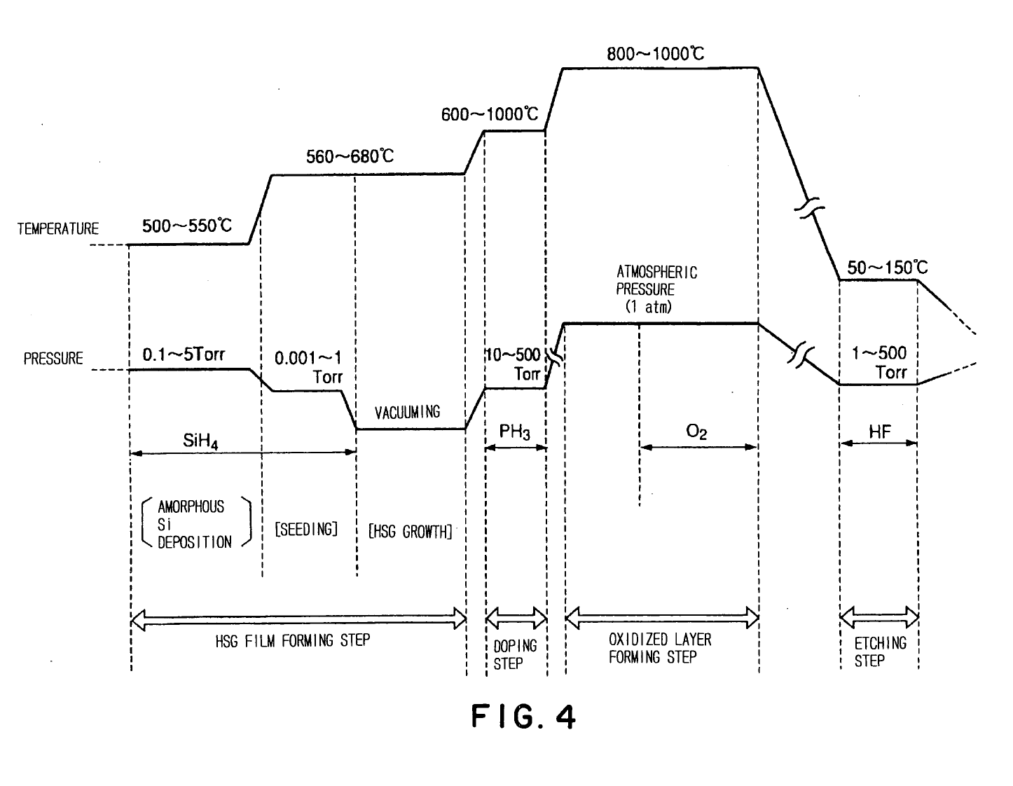

In the first embodiment, the hemispherical grained film 94 (see, FIG. 3(C)), including the base part 90 and the hemispherical grains 96, is formed of a non-doped silicon. However, not limited thereto, the hemispherical grained film 94 may be doped with impurities. FIG. 4 is a time chart showing the process flow of the second embodiment of the present invention method.

As shown in FIG. 4, a doping step of doping the hemispherical grained film 94 with impurities is interposed between the HSG film forming step and the oxidized layer forming step. In the doping step, PH₃ (Phosphine) gas is used for doping the hemispherical grained film 94 with phosphorus (P) as an impurity. In this process step, the process temperature may be in the range of 600° C. to 1,000° C., and a process pressure may be in the range of 10 Torr to 500 Torr. However, the process conditions of the doping step are not limited to the above.

Alternatively, the hemispherical grained film may be doped with phosphorus, by supplying PH₃ gas simultaneously with the supply of SiH₄ gas in the amorphous silicon film forming step and the nuclei seeding step (excluding the hemispherical grain growing step) of the HSG film forming step in the first embodiment.

In the respective embodiments, although all the process steps are performed in a common film-forming apparatus 20, the respective process steps may be performed in different processing apparatuses. Alternatively, the HSG film forming step and one of the oxidized layer forming step and the etching step may be performed in a common film-forming apparatus 20.

A dry etch is performed in the etching step, but a wet etch may be performed. In this case, diluted hydrofluoric acid (DHF) may be used as an etching liquid.

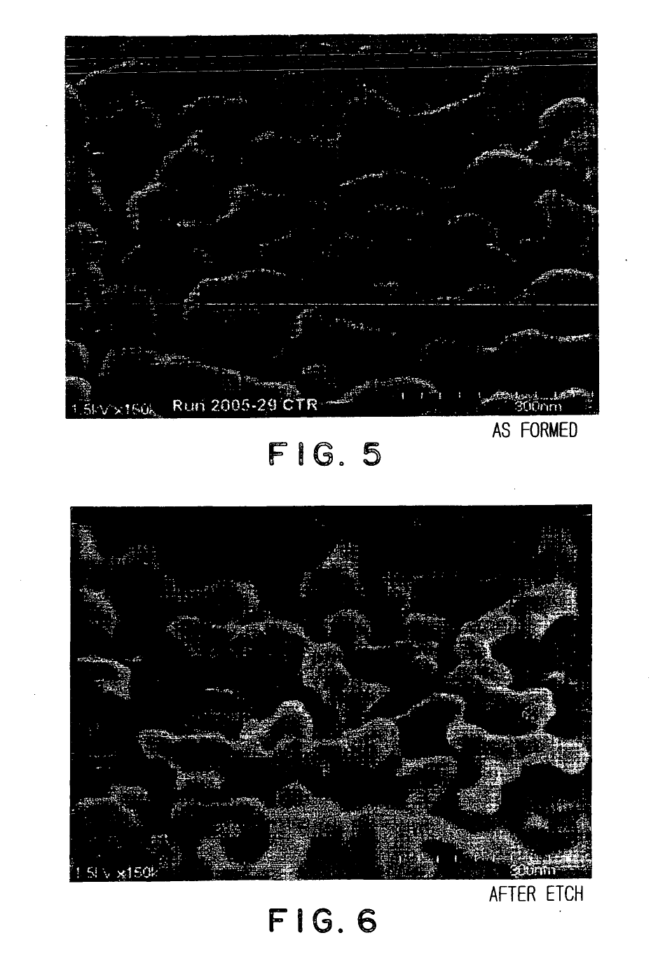

An HSG film was formed, oxidized and etched in accordance with the method of the present invention. The oxidized layer was etched by a wet etch using diluted hydrofluoric acid (DHF). FIG. 5 is an electron micrograph of hemispherical grains which was taken immediately after the grains were formed; and FIG. 6 is an electron micrograph of the hemispherical grains, which was taken after the grains were subjected to the oxidizing step and the etching step. As is apparent from FIGS. 5 and 6, the size of the hemispherical grains subjected to the oxidizing step and the etching step is smaller. The average size of the hemispherical grains shown in FIG. 5 (As Formed) was about 50 nm, while the average size of the hemispherical grains shown in FIG. 6 (After Etch) was about 30 nm. Thus, it was confirmed that the size of the grains can be significantly reduced.

In the above embodiments, SiH₄ gas is used as an Si-containing gas for the HSG film formation. However, not limited thereto, it is possible to use, as the Si-containing gas, one or more gases selected from the group consisting of: dichlorosilane (DCS), monosilane [SiH₄], disilane [Si₂H₆], hexachlorodisilane [Si₂Cl₆] (HCD), hexamethyldisilazane (HMDS), tetrachlorosilane [SiHCl₃] (TCS), disylilamine (DSA), trisylilamine (TSA), bis tertiary-butylamino silane (BTBAS), [(CH₃)₃SiH] (Trimethylsilane), [(CH₃)₃SiN₃] (Trimethylsilylazide), [SiF₄], [SiCl₃F], [SiI₄], and [Si₂F₆].

In the above embodiments, O₂ gas is used as an oxidizing gas. However, not limited thereto, it is possible to use, as the oxidizing gas, one or more gases selected from the group consisting of: N₂O, H₂O, O₂, O₃, O* (active species), NO, NO₂, CO₂, and CO.

HF gas or diluted hydrofluoric acid is used for etching the oxidized layer. However, not limited thereto, any etching agent may be used provided that it can selectively etch SiO₂, i.e., the oxidized layer.

A batch type processing vessel is not limited to the single tube structure type as shown in FIG. 1, and a processing vessel of a dual-tube structure having an inner pipe and an outer pipe may be used. Further, a film-forming apparatus of a single-wafer processing type, which processes semiconductor wafers one by one, may be used instead of the film-forming apparatus of the batch-type which processes a plurality of wafers simultaneously.

The material of the HSG film is not limited to silicon. Any material may be used for the HSG film as long as hemispherical grains can be formed on an amorphous film of the material by the nuclei-seeding and the migration. For example SiGe (silicon germanium) is used as the material forming the film.

The process object is not limited to a semiconductor wafer, and may be a glass substrate, an LCD substrate and so on.

What is claimed is:

1. A film-forming method comprising:
(a) irradiating a film-forming gas to a surface of a process object to seed crystal nuclei, and causing growth of the nuclei, thereby forming a hemispherical grained film having crystalline hemispherical grains on the surface of the process object;
(b) oxidizing a surface part of the hemispherical grained film, thereby forming an oxidized layer at the surface part of the hemispherical grained film; and
(c) etching the oxidized layer to remove the same.

2. The method according to claim 1, wherein the steps (a), (b) and (c) are performed in a common processing vessel.

3. The method according to claim 1, wherein at least two of the steps (a), (b) and (c) are performed in processing vessels different from each other.

4. The method according to claim 1, wherein, in the step (c), a dry etch is performed by using hydrogen fluoride gas.

5. The method according to claim 1, wherein, in the step (c), a wet etch is performed by using a diluted hydrofluoric acid.

6. The method according to claim 1, wherein the hemispherical grained film is doped with impurities.

7. The method according to claim 6, wherein the hemispherical grained film is doped with impurities between the steps (a) and (b).

8. The method according to claim 6, wherein the hemispherical grained film is doped with impurities in the step (a).

9. The method according to claim 1, wherein a base part of the hemispherical grained film comprises an amorphous silicon, and the crystalline hemispherical grains comprise a crystalline silicon.

10. A film-forming apparatus comprising:
a processing vessel adapted to contain a process object and adapted to be evacuated;
a support member adapted to support the process object in the processing vessel;
a film-forming gas supply system adapted to supply a film-forming gas into the processing vessel;
an oxidizing gas supply system adapted to supply an oxidizing gas into the processing vessel;
an etching gas supply system adapted to supply an etching gas into the processing vessel;
a heater adapted to heat the process object contained in the processing vessel; and
a controller (a) configured to control the film-forming gas supply system to irradiate the film-forming gas to a surface of a process object to seed crystal nuclei, and causing growth of the nuclei, thereby forming a hemispherical grained film having crystalline hemispherical grains, on the surface of the process object; (b) configured to control the oxidizing gas supply system to supply the oxidizing gas to the process object to oxidize a surface part of the hemispherical grained film, thereby forming an oxidized layer at the surface part of the hemispherical grained film; and (c) configured to control the etching gas supply system to supply the etching gas to the process object to etch the oxidized layer to remove the same.

11. A data storage medium storing a control program therein, wherein, upon execution of the control program by a control computer of a film-forming apparatus, the film forming apparatus performs a film-forming method including:
(a) irradiating a film-forming gas to a surface of a process object to seed crystal nuclei, and causing growth of the nuclei, thereby forming a hemispherical grained film having crystalline hemispherical grains on the surface of the process object;
(b) oxidizing a surface part of the hemispherical grained film, thereby forming an oxidized layer at the surface part of the hemispherical grained film; and
(c) etching the oxidized layer to remove the same.
